(19) United States
(12) Patent Application Publication
(10) Pub. No.: US 2024/0254618 A1
(43) Pub. Date: Aug. 1, 2024

(54) METAL MASK STRUCTURE

(71) Applicant: Darwin Precisions Corporation, Hsinchu County (TW)

(72) Inventors: HAN-FANG LI, Hsinchu County (TW); CHIAO-LING HUANG, Hsinchu County (TW)

(21) Appl. No.: 18/381,191

(22) Filed: Oct. 18, 2023

(30) Foreign Application Priority Data
Jan. 30, 2023 (TW) 112103131

(51) Int. Cl. C23C 16/04

(52) U.S. Cl. CPC C23C 16/042

(57) ABSTRACT

The present invention provides a metal mask structure, including: an outer frame, a protrusion region, and a first connection region. The outer frame surrounds and defines a central hollowed-out region and includes at least a first side frame. The protrusion region protrudes from the first side frame toward the central hollowed-out region, and is provided with at least one hole. The protrusion region is connected to the first side frame at a connection side edge. The first connection region connects the protrusion region to the first side frame at one end of the connection side edge, and includes a first side edge, a second side edge, and a third side edge. The first side edge continues from the connection side edge, the second side edge extends transversely from a junction of the first side edge and the connection side edge toward the central hollowed-out region, and two ends of the third side edge are respectively connected to endpoints of the first side edge and the second side edge away from the connection side edge.

### CROSS-REFERENCE TO RELATED APPLICATION

This application claims the priority benefit of Taiwan application serial no. 112103131 filed on Jan. 30, 2023. The entirety of the above-mentioned patent application is hereby incorporated by reference herein and made a part of this specification.

### TECHNICAL FIELD

The present invention relates to a metal mask structure. Specifically, the present invention relates to a metal mask structure having a protrusion region.

### BACKGROUND

In order to manufacture various devices or components having predetermined patterns, a fine metal mask (FMM) may have various implementations. In order to arrange a small functional block on an electronic device, for example but not limited to arranging a camera or a microphone on a smart phone, a corresponding fine metal mask needs to be configured. However, for such small functional blocks, if a part of the fine metal mask with a fully etched hole has an excessively small area or has an undesirable support structure, defects such as overall or partial warping, denting, or breaking are likely to occur. Carrying on with the above, such defects further reduce the accuracy of manufacturing the electronic device. Therefore, a metal mask structure that can be configured to accurately manufacture a small functional block of the electronic device and has a predetermined stability and reliability needs to be developed.

### SUMMARY

### Technical Means for Resolving the Problems

In order to solve the above problem, a metal mask structure is provided according to an embodiment of the present invention, including: an outer frame, surrounding and defining a central hollowed-out region, and including at least a first side frame; a protrusion region, protruding from the first side frame toward the central hollowed-out region, and provided with at least one hole, where the protrusion region is connected to the first side frame at a connection side edge; and a first connection region, connecting the protrusion region to the first side frame at one end of the connection side edge, and including a first side edge, a second side edge, and a third side edge. The first side edge continues from the connection side edge, the second side edge extends transversely from a junction of the first side edge and the connection side edge toward the central hollowed-out region, and two ends of the third side edge are respectively connected to endpoints of the first side edge and the second side edge away from the connection side edge.

Efficacy Compared with the Prior Art

Based on the metal mask structure provided in the embodiments of the present invention, a stress on a part of the protrusion region of the metal mask structure provided with one or more holes may be reduced or eliminated. In this way, overall or partial warping, denting, or breaking of the protrusion region of the metal mask structure may be reduced or eliminated, thereby further reducing or eliminating a deviation caused during manufacturing of a predetermined pattern by using the metal mask structure. Carrying on with the above, based on the metal mask structure provided in the embodiments of the present invention, the accuracy of the predetermined pattern during manufacturing of a partially relatively small block can be further improved. Therefore, the quality of the manufactured electronic device or component can be improved by enhancing the reliability and stability of the used metal mask structure.

### BRIEF DESCRIPTION OF THE DRAWINGS

FIG. 1 is a schematic top view of a metal mask structure having a protrusion region and a connection region according to an embodiment of the present invention.

FIG. 2 is a schematic enlarged view of a region R in FIG. 1 according to an embodiment of the present invention.

FIG. 3 is a schematic enlarged view of a first connection region according to an embodiment of the present invention.

FIG. 4 is a schematic enlarged view of a first connection region according to another embodiment of the present invention.

FIG. 5 is a schematic enlarged view of a first connection region according to yet another embodiment of the present invention.

FIG. 6 is a schematic diagram that shows finished product photos of different implementations of changes in an area proportion of a first connection region relative to a protrusion region according to some examples.

### DETAILED DESCRIPTION

Various embodiments are to be described below, and a person with ordinary knowledge in the technical field can easily understand the spirit and principles of the present invention by referring to the accompanying drawings. However, although some specific embodiments are to be specifically described herein, these embodiments are only illustrative and are not to be considered restrictive or exhaustive in all aspects. Therefore, various changes and modifications of the present invention should be obvious and easily implemented for a person with ordinary knowledge in the technical field without departing from the spirit and principles of the present invention.

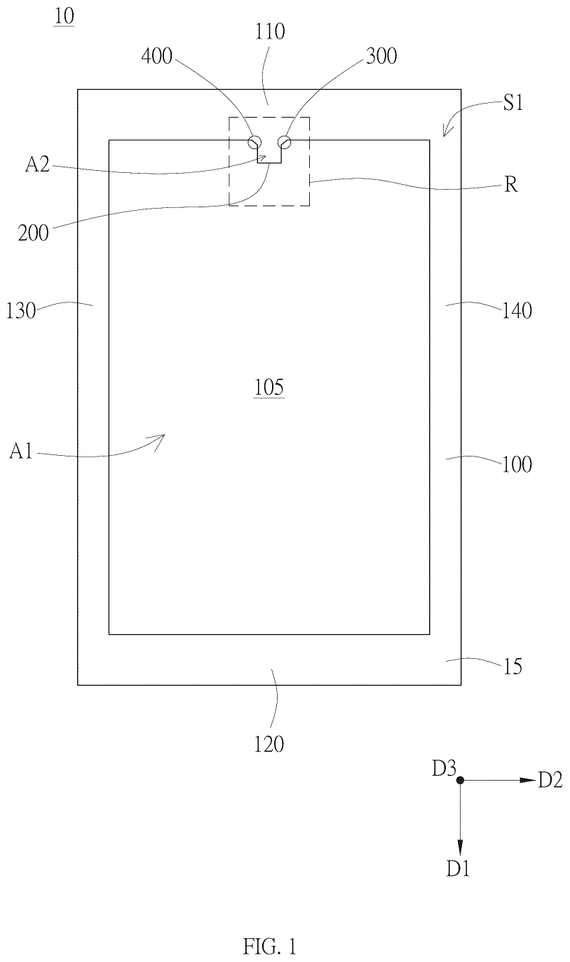

FIG. 1 shows a metal mask structure 10 according to an embodiment of the present invention. The metal mask structure 10 may include at least an outer frame 100, a protrusion region 200, and a first connection region 300 connecting the outer frame 100 to the protrusion region 200. According to some embodiments, the outer frame 100, the protrusion region 200, and the first connection region 300 may be made of a plate 15. For example, the plate 15 may be an invar alloy, and the plate 15 may have a thickness in a range of 20 μm to 100 μm. That is to say, according to this embodiment, the metal mask structure 10 may have a thickness in a range of about 20 μm to 100 μm in a direction D3. However, the material and thickness of the plate 15 for manufacturing the metal mask structure 10 described above are merely examples, and another embodiment of the present invention is not limited thereto.

Carrying on with the above, according to the embodiments of the present invention, the outer frame 100 may surround and define at least a completely hollow central hollowed-out region 105. For example, according to this embodiment, the outer frame 100 may include a first side frame 110, a second side frame 120, a third side frame 130, and a fourth side frame 140, which surround and define a central hollowed-out region 105. Specifically, according to this embodiment, the outer frame 100 may include the first side frame 110 and the second side frame 120 extending in a direction D2, and the third side frame 130 and the fourth side frame 140 extending in a direction D1. Carrying on with the above, in this embodiment, the outer frame 100 may be in the form of a quadrilateral rectangle surrounding and defining a central hollowed-out region 105. However, according to another embodiment, the outer frame 100 may also surround and defined the central hollowed-out region 105 in other shapes of different numbers of side edges or even in an irregular shape, and a plurality of central hollowed-out regions 105 may also be arranged. For example, the outer frame 100 may alternatively include only the first side frame 110, which may be in the form of a circle or an oval surrounding and defining the central hollowed-out region 105. Alternatively, the outer frame 100 may be formed in a grid shape and therefore surround and define a plurality of central hollowed-out regions 105 arranged in a matrix form. Carrying on with the above, a person with ordinary knowledge in the technical field should be able to derive these changes correspondingly with reference to this specification, and details are not described in this specification again.

Based on the above, according to the embodiments of the present invention, based on the quantity, shapes, and implementations of the central hollowed-out regions 105, a part of the outer frame 100 surrounding and defining each of the central hollowed-out regions 105 may include at least the first side frame 110 defining at least one central hollowed-out region 105.

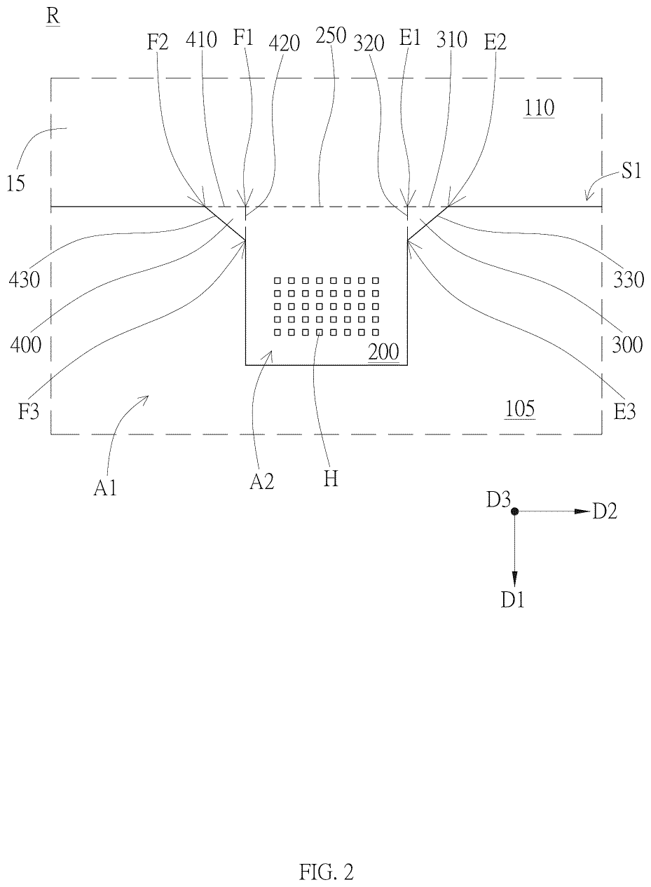

Then, referring to FIG. 1 and FIG. 2 of the enlarged region R in FIG. 1, according to this embodiment, a protrusion region 200 having a relatively small area may protrude from the first side frame 110 toward the central hollowed-out region 105. For example, according to some embodiments, an area A2 of the protrusion region 200 may be less than an area A1 of the central hollowed-out region 105. According to this embodiment, at least one hole H may be arranged in the protrusion region 200 based on a predetermined pattern, so as to layout the predetermined pattern of a device or a component in the subsequent process. Carrying on with the above, the metal mask structure 10 having the hole H of the predetermined pattern may be manufactured by using a procedure of chemical wet etching methods such as base material preparation, film pressing, exposure, development, curing and baking, etching, and photoresist removal. However, the above are merely examples, and may not be limited thereto according to different embodiments. For example, the metal mask structure 10 having the hole H of the predetermined pattern may be manufactured by using a procedure of electrocasting, and the details are not described herein again.

Carrying on with the above, one or more holes H are arranged in the protrusion region 200, and the stability and reliability of the protrusion region 200 may be unexpectedly reduced in a case that the area A2 of the protrusion region 200 is relatively small. In particular, in the configuration for depositing the predetermined pattern on a predetermined device or component through vapor deposition, the at least one hole H may be a fully etched hole formed through the thickness of the plate 15, which leads to a thinner and more fragile structure of the protrusion region 200. Carrying on with the above, according to the implementation of the metal mask structure 10, the protrusion region 200 is connected to the first side frame 110 only at a connection side edge 250 between an endpoint E1 and an endpoint F1. That is to say, the protrusion region 200 may be only partially arranged to correspond to a part of the first side frame 110, and therefore may receive relatively less support from the first side frame 110, causing the overall protrusion region 200 to be less stable or prone to unexpected concentration of stress on the connection side edge 250 where the protrusion region 200 is connected to the first side frame 110. For example, according to some embodiments, the endpoint E1 and the endpoint F1 are particularly prone to unexpected concentration of the stress, and may result in corresponding defects.

In order to solve this problem, according to this embodiment, at least one first connection region 300 may further be arranged to connect the protrusion region 200 to the first side frame 110 at the endpoint E1 of one end of the connection side edge 250. In detail, the first connection region 300 may include a first side edge 310, a second side edge 320, and a third side edge 330. Carrying on with the above, the first side edge 310 continues from the connection side edge 250, and is a junction of the first connection region 300 and the first side frame 110. In addition, the second side edge 320 may extend transversely from a junction of the first side edge 310 and the connection side edge 250 (that is, the endpoint E1) toward the central hollowed-out region 105, and is a junction of the first connection region 300 and the protrusion region 200. Carrying on with the above, two ends of the third side edge 330 (that is, an endpoint E2 and an endpoint E3) may be respectively connected to endpoints of the first side edge 310 and the second side edge 320 away from the connection side edge 250. In this way, the first connection region 300 may be surrounded and defined by the first side edge 310, the second side edge 320, and the third side edge 330. Carrying on with the above, according to this embodiment, through arrangement of the first connection region 300, the protrusion region 200 may be further strengthened and stabilized, and the stress concentration on a corner junction (that is, an endpoint E1) of the protrusion region 200 and the first side frame 110 may be reduced or eliminated. Therefore, the stress on the protrusion region 200 extending from the first side frame 110 can be reduced or eliminated to avoid unexpected warping, denting, or breaking, thereby improving the reliability and accuracy of the overall metal mask structure 10.

According to some embodiments, the protrusion region 200 may correspond to a functional region of a local small block of an electronic device or a component. For example, the protrusion region 200 may be configured for a block such as an under-screen camera lens or a microphone on a mobile phone to be made through vapor deposition. Therefore, according to the embodiment of the present invention, the accuracy and quality during manufacturing of these blocks by using the metal mask structure 10 may be further improved. However, according to various embodiments of the present invention, corresponding suitable functional blocks that can be manufactured by the protrusion region 200 are not limited thereto, and may have various application implementations.

In addition, according to some embodiments of the present invention, in addition to the relatively fragile metal mask structure 10 having the protrusion region 200 provided with the hole H, the first connection region 300 may also be similarly arranged on the metal mask structure having the protrusion region without a hole. For example, the first connection region 300 according to various embodiments of the present invention may also be correspondingly applied to a fine cover mask (FCM), to further strengthen the originally stable structure, thereby improving the tensioning or supporting capability thereof. Carrying on with the above, the corresponding arrangement and changes may be inferred with reference to the description of the present invention, and the details are not described herein again.

Further, according to some embodiments of the present invention, only the first connection region 300 may be arranged. However, according to this embodiment, a second connection region 400 symmetrical to the first connection region 300 may be further arranged. In detail, referring to FIG. 2, the second connection region 400 may connect the protrusion region 200 to the first side frame 110 at the endpoint F1 of the other end of the connection side edge 250, and include a fourth side edge 410, a fifth side edge 420, and a sixth side edge 430. Similar to the first side edge 310, the second side edge 320, and the third side edge 330 described above, the fourth side edge 410 may continue from the connection side edge 250, while the fifth side edge 420 extends transversely from a junction of the fourth side edge 410 and the connection side edge 250 (that is, the endpoint F1) toward the central hollowed-out region 105, and two ends of the sixth side edge 430 are respectively connected to endpoints (that is, an endpoint F2 and an endpoint F3) of the fourth side edge 410 and the fifth side edge 420 away from the connection side edge 250. Carrying on with the above, through arrangement of the second connection region 400, the protrusion region 200 may be further strengthened and stabilized, and the stress concentration on a corner junction (that is, an endpoint F1) of the protrusion region 200 and the first side frame 110 may be reduced or eliminated. Therefore, the stress on the protrusion region 200 extending from the first side frame 110 can be reduced or eliminated to avoid unexpected warping, denting, or breaking, thereby improving the reliability and accuracy of the overall metal mask structure 10. The contents are all the same or similar to those of the first connection region 300. Therefore, the first connection region 300 will be described in detail below as an example, and details of the second connection region 400 are not described again.

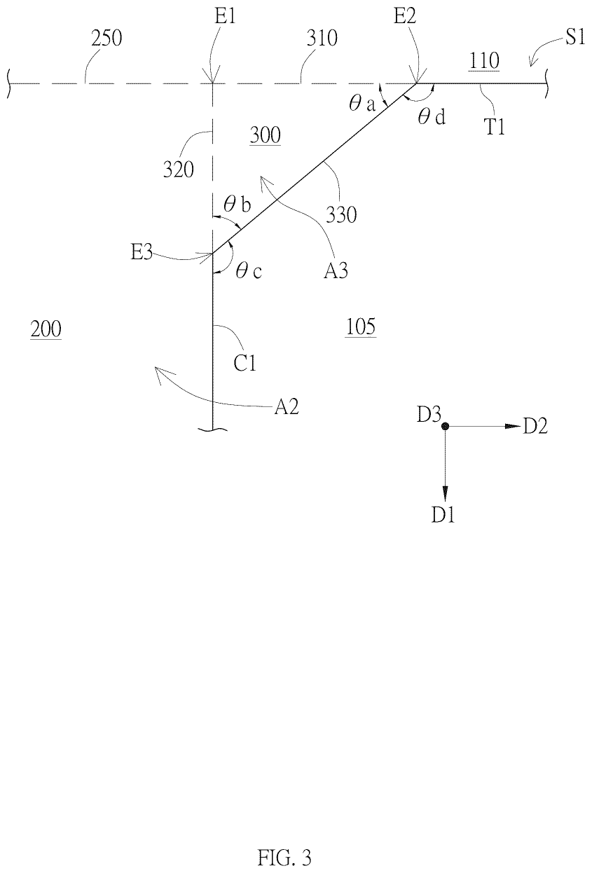

Carrying on with the above, further referring to FIG. 3 of the schematic enlarged view of the first connection region 300 in FIG. 2, observed from the front surface S1 of the metal mask structure 10, the first connection region 300 may be a block surrounded and defined by the first side edge 310, the second side edge 320, and the third side edge 330, and may have a shape with a generally triangular outline according to some embodiments, but is not limited thereto. Carrying on with the above, according to this embodiment, an area A3 of the first connection region 300 may be in a range of 0.5% to 20% of the area A2 of the protrusion region 200. For example, the area A3 of the first connection region 300 may be in a range of 0.5% to 10% of the area A2 of the protrusion region 200. Based on this range, the first connection region 300 may significantly relieve or disperse the stress, thereby avoiding overall or partial warping, denting, or breaking of the protrusion region 200 and the structure at the junction of the protrusion region 200 and the first side frame 110 as a result of stress concentration on or around the protrusion region 200.

Further, in order to reduce the stress concentration, according to this embodiment, an included angle θa between the first side edge 310 and the third side edge 330 may be less than 90 degrees. In contrast, an included angle θd between a contour line T1 of the first side frame 110 continuing and extending from the first side edge 310 and the third side edge 330 is greater than 90 degrees. Through the configuration, the stress concentration on the endpoint E2 can be reduced or eliminated. Similarly, according to this embodiment, an included angle θb between the second side edge 320 and the third side edge 330 may be less than 90 degrees. In contrast, the protrusion region 200 may be connected to the first connection region 300 based on the second side edge 320 as a junction, and an included angle θc between a contour line C1 of the protrusion region 200 continuing and extending from the second side edge 320 and the third side edge 330 may be greater than 90 degrees. Through the configuration, the stress concentration on the endpoint E3 can be reduced or eliminated. In addition, as detailed above, since the first side frame 110 is connected to the protrusion region 200 through the intermediate first connection region 300, the endpoint E1 may not directly bear a stress supporting the protrusion region 200. Therefore, according to this embodiment, in addition to reducing or avoiding the stress concentration on the endpoint E2 and the endpoint E3, the stress concentration on the endpoint E1 may also be reduced and eliminated.

As described above, through arrangement of the first connection region 300 of the above design, a defect of overall stress concentrated on a specific endpoint, for example, an endpoint of a 90-degree vertical right angle, can be improved, and the overall stability of the arrangement of the protrusion region 200 and the accuracy during manufacturing of a device or a component having the predetermined pattern by using the metal mask structure can be improved.

According to some embodiments, the protrusion region 200 may alternatively be formed in another shape except a rectangle. For example, the protrusion region 200 may alternatively be formed in an oval or a drop shape without obvious turns in the contour line C1, changes thereof may be inferred according to the above description, and the details are not described herein again.

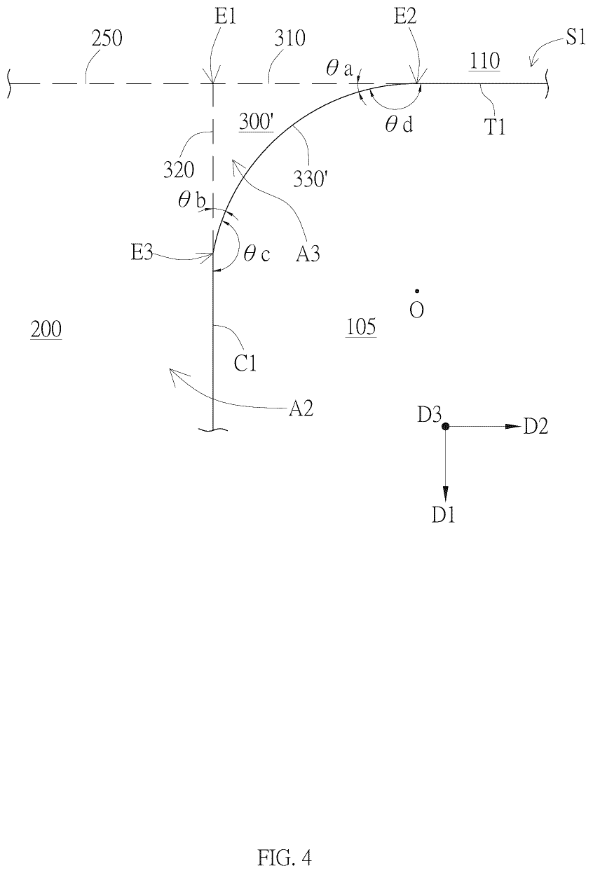

In addition, according to another embodiment of the present invention, to reduce or eliminate formation of a right angle, a sharp corner, or another type of stress concentration point, the third side edge 330 may not be formed as a straight line as shown in FIG. 3. For example, referring to an embodiment of FIG. 4, a third side edge 330′ may be a curve. Further, according to some embodiments, a center O of curvature of the curve may be located on a side of the third side edge 330′ facing away from a first connection region 300′. As a result, the endpoint E2 and the endpoint E3 that are prone to stress concentration may be further transitioned with a gentler change in curvature, and the overall stability of the third side edge 330′ may be improved, thereby reducing or avoiding stress concentration on the endpoint E2, the endpoint E3, and the third side edge 330′. However, the third side edge 330′ having a constant center O of curvature and a constant curvature shown herein is merely an example, and according to another embodiment, the curve of the third side edge may also have a varying curvature and a varying center of curvature, and may be an irregular arc. Carrying on with the above, a person with ordinary skill in the technical field should understand that the curve of the third side edge according to another embodiment of the present invention is not limited to the implementation specifically described herein.

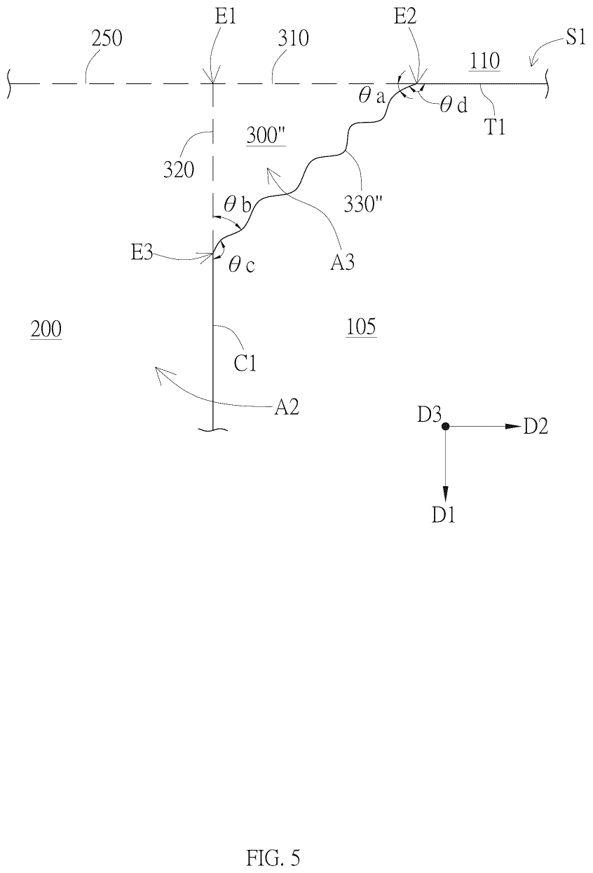

Furthermore, referring to FIG. 5, according to some other embodiments, a first connection region 300″ may also include a third side edge 330″ extending in a meandering manner. For example, the third side edge 330″ may be a wavy line. Therefore, the stress concentration on the third side edge 330″ may be further avoided, and the stress can be dispersed by the third side edge 330″ extending in a meandering manner, thereby improving the stability and reliability of an edge of the first connection region 300″.

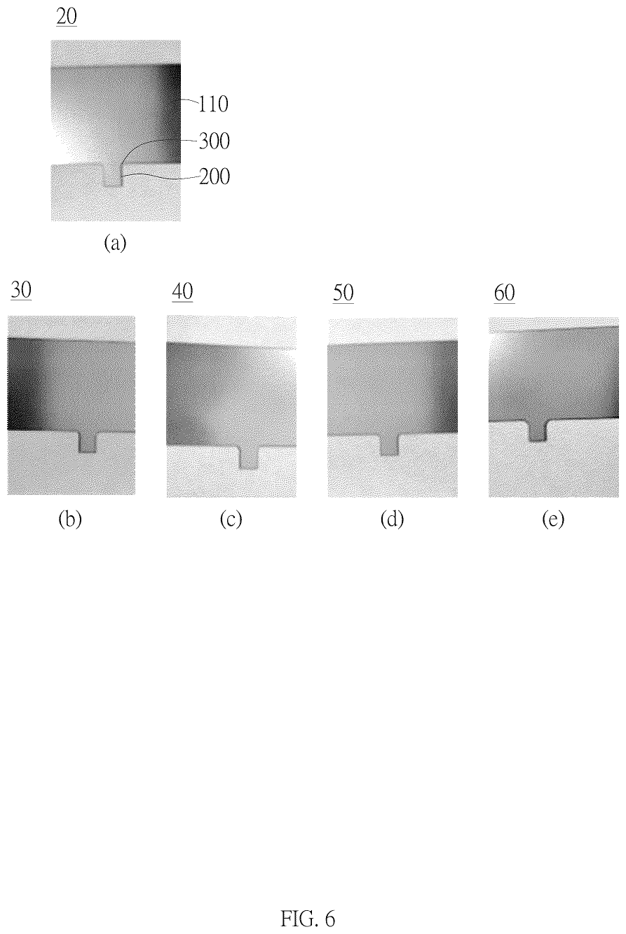

Next, some examples that the first connection region 300 is configured in different area proportions based on the implementation of FIG. 3 are shown with reference to FIG. 6.

Carrying on with the above, referring to FIG. 6, part (a) shows an example photo of a metal mask structure 20 configured in a proportion of 0.35% of the area of the first connection region 300 relative to the protrusion region 200, part (b) shows an example photo of a metal mask structure 30 configured in a proportion of 0.56% of the area of the first connection region 300 relative to the protrusion region 200, part (c) shows an example photo of a metal mask structure 40 configured in a proportion of 1.34% of the area of the first connection region 300 relative to the protrusion region 200, part (d) shows an example photo of a metal mask structure 50 configured in a proportion of 3.02% of the area of the first connection region 300 relative to the protrusion region 200, and part (e) shows an example photo of a metal mask structure 60 configured in a proportion of 5.37% of the area of the first connection region 300 relative to the protrusion region 200. Carrying on with the above, in the metal mask structure 20 shown in part (a), overall or partial warping, denting, or breaking may be clearly found through microscopic magnification, and is not significantly improved compared with the arrangement without the first connection region 300. However, in the metal mask structure 30 shown in part (b), the metal mask structure 40 shown in part (c), the metal mask structure 50 shown in part (d), and the metal mask structure 60 shown in part (e), the defects of the overall or partial warping, denting, breaking may be significantly reduced compared with the arrangement without the first connection region 300.

Based on the above, based on the metal mask structure provided in the embodiments of the present invention, changes and defects of a partially protruding protrusion region as a result of the stress concentration can be significantly reduced by setting a fillet (round corner) or increasing an area of the fillet (round corner). For example, the breaking of the metal mask structure may be reduced or eliminated, and the defect of the denting or warping may be reduced or eliminated, or at least an amount of sagging or upwarping (a height deviation) of the denting or the warping may be reduced. Therefore, based on the metal mask structure provided in the embodiments of the present invention, flatness and supportiveness of the overall metal mask structure can be further improved, the stability and reliability of the metal mask structure can be improved and strengthened, and the accuracy during manufacturing of a device or a component having the predetermined pattern by using the metal mask structure can be correspondingly improved.

The above descriptions are merely some preferred embodiments of the present invention. It should be noted that various changes and modifications can be made to the present invention without departing from the spirit and principles of the present invention. A person of ordinary skill in the art should clearly understand that the present invention is defined by the appended claims, and all possible changes such as substitutions, combinations, modifications, and diversions are within the scope of the present invention defined by the scope of the appended claims.

### REFERENCE NUMERALS

10, 20, 30, 40, 50, 60: metal mask structure
15: plate
100: outer frame
105: central hollowed-out region
110: first side frame
120: second side frame
130: third side frame
140: fourth side frame
200: protrusion region
250: connection side edge
300, 300′, 300″: first connection region
310: first side edge
320: second side edge
330, 330′, 330″: third side edge
400: second connection region
410: fourth side edge
420: fifth side edge
430: sixth side edge
A1, A2, A3: area
C1: contour line
D1, D2, D3: direction
E1, E2, E3: endpoint
F1, F2, F3: endpoint
H: hole
O: center
R: region
S1: front surface
T1: contour line
θa, θb, θc, θd: included angle

What is claimed is:

1. A metal mask structure, comprising:
an outer frame, surrounding and defining a central hollowed-out region, and comprising at least a first side frame;
a protrusion region, protruding from the first side frame toward the central hollowed-out region, and provided with at least one hole, wherein the protrusion region is connected to the first side frame at a connection side edge; and
a first connection region, configured to connect the protrusion region to the first side frame at one end of the connection side edge, and comprising a first side edge, a second side edge, and a third side edge, wherein
the first side edge continues from the connection side edge, the second side edge extends transversely from a junction of the first side edge and the connection side edge toward the central hollowed-out region, and two ends of the third side edge are respectively connected to endpoints of the first side edge and the second side edge away from the connection side edge.

2. The metal mask structure according to claim 1, further comprising a second connection region, wherein the second connection region is configured to connect the protrusion region to the first side frame at the other end of the connection side edge, and comprises a fourth side edge, a fifth side edge, and a sixth side edge, wherein
the fourth side edge continues from the connection side edge, the fifth side edge extends transversely from a junction of the fourth side edge and the connection side edge toward the central hollowed-out region, and two ends of the sixth side edge are respectively connected to endpoints of the fourth side edge and the fifth side edge away from the connection side edge.

3. The metal mask structure according to claim 1, wherein the third side edge is a curve.

4. The metal mask structure according to claim 3, wherein a center of curvature of the curve is located on a side of the third side edge facing away from the first connection region.

5. The metal mask structure according to claim 1, wherein the third side edge is a wavy line.

6. The metal mask structure according to claim 1, wherein an area of the first connection region is in a range of 0.5% to 20% of an area of the protrusion region.

7. The metal mask structure according to claim 6, wherein an area of the first connection region is in a range of 0.5% to 10% of an area of the protrusion region.

8. The metal mask structure according to claim 1, wherein an included angle between the first side edge and the third side edge is less than 90 degrees.

9. The metal mask structure according to claim 1, wherein an included angle between the second side edge and the third side edge is less than 90 degrees.

10. The metal mask structure according to claim 1, wherein the protrusion region is connected to the first connection region based on the second side edge as a junction, and an included angle between a contour line of the protrusion region continuing and extending from the second side edge and the third side edge is greater than 90 degrees.

11. The metal mask structure according to claim 1, wherein an included angle between a contour line of the first side frame continuing and extending from the first side edge and the third side edge is greater than 90 degrees.

12. The metal mask structure according to claim 1, wherein the outer frame, the protrusion region, and the first connection region are made of a plate, and the plate has a thickness in a range of 20 μm to 100 μm.

13. The metal mask structure according to claim 1, wherein the at least one hole is a fully etched hole.

14. The metal mask structure according to claim 1, wherein an area of the protrusion region is less than an area of the central hollowed-out region.
